(19) United States
(12) Patent Application Publication
(10) Pub. No.: US 2025/0221322 A1
(43) Pub. Date: Jul. 3, 2025

(54) RESISTIVE MEMORY CELL, RESISTIVE MEMORY ARRAY INCLUDING THE RESISTIVE MEMORY CELL AND METHOD OF MANUFACTURING THE RESISTIVE MEMORY CELL

(71) Applicant: SK hynix Inc., Icheon-si (KR)

(72) Inventors: Won Tae KOO, Icheon-si (KR); Young Jae KWON, Icheon-si (KR)

(21) Appl. No.: 18/674,618

(22) Filed: May 24, 2024

(30) Foreign Application Priority Data
Jan. 3, 2024 (KR) 10-2024-0000929

(51) Int. Cl. H10N 70/00; H10B 63/00; H10N 70/20

(52) U.S. Cl. CPC H10N 70/882; H10B 63/84; H10N 70/021; H10N 70/24; H10N 70/841; H10N 70/8833

(57) ABSTRACT

A resistive memory cell may include a lower electrode, an upper electrode, a variable resistance layer and a charge bypass layer. The upper electrode may be substantially perpendicular to the lower electrode. The variable resistance layer may be interposed between the lower electrode and the upper electrode. The variable resistance layer may have a resistance changed by a conductive filament, which may include a reversibly generated oxygen vacancy, based on an electric field between the lower electrode and the upper electrode. When a voltage, which may be higher than a program voltage applied to the upper electrode, may be applied to the lower electrode, the charge bypass layer may include a plurality of discontinuous vertical grain boundaries and a plurality of horizontal grain boundaries connected between the discontinuous vertical grain boundaries.

### CROSS-REFERENCE TO RELATED APPLICATION

The present application claims priority under 35 U.S.C. § 119(a) to Korean application number 10-2024-0000929, filed on Jan. 3, 2024, in the Korean Intellectual Property Office, which is incorporated herein by reference in its entirety.

### BACKGROUND

### 1. Technical Field

Various embodiments generally relate to a semiconductor integrated circuit technology, more particularly, to a resistive memory cell, a resistive memory array including the resistive memory cell and a method of manufacturing the resistive memory cell.

### 2. Related Art

Recently, as demands for portable digital application devices such as digital cameras, tablet computers, smart phones, etc., have increased, the market for non-volatile memory devices has greatly expanded.

A NAND flash memory device is a typical programmable non-volatile memory device with improved storage capacity and a multi-level and/or a three-dimensional cell structure. However, fundamental limits of NAND flash memory devices are revealed from difficulty in manufacturing to a long drive time caused by a block access architecture.

As an alternative to NAND flash memory devices, a resistive memory device may use a variable resistor with a resistance that can be changed or reversed.

The resistive memory device may include a variable resistance layer. The resistive memory device may switch between a reversible low resistance state and high resistance state that reflects a data state. Thus, the resistive memory device may be rapidly switched at a speed of no more than about 10 ns (nanoseconds). The resistive memory device may be driven by low power of about 1 pJ (picojoule)/operation. Further, the resistive memory device may include a simple cell to facilitate effective scaling.

### SUMMARY

According to example embodiments, there may be provided a resistive memory cell. The resistive memory cell may include a lower electrode, an upper electrode, a variable resistance layer and a charge bypass layer. The upper electrode may be substantially perpendicular to the lower electrode. The variable resistance layer may be interposed between the lower electrode and the upper electrode. The variable resistance layer may have a resistance changed by a conductive filament, which may include a reversibly generated oxygen vacancy, based on an electric field between the lower electrode and the upper electrode. When a voltage, which may be higher than a program voltage applied to the upper electrode, may be applied to the lower electrode, the charge bypass layer may include a plurality of discontinuous vertical grain boundaries and a plurality of horizontal grain boundaries connected between adjacent discontinuous vertical grain boundaries.

In example embodiments, the charge bypass layer may include at least one conductive two-dimensional (2D) layer.

According to example embodiments, there may be provided a resistive memory array. The resistive memory array may include a plurality of bit lines, a plurality of word lines intersected with the bit lines and a plurality of resistive memory cells positioned at between the bit lines and the word lines. The resistive memory cell may include a program electrode, a ground electrode, a variable resistance layer and a charge bypass layer. The program electrode may be electrically connected to the bit lines to receive a program voltage. The ground electrode may be electrically connected to the word lines to generate a vertical electric field together with the program electrode. The variable resistance layer may be interposed between the program electrode and the ground electrode. The variable resistance layer may have a resistance changed by a conductive filament, which may include oxygen vacancies selectively formed based on the vertical electric field. The charge bypass layer may be arranged between the ground electrode and the variable resistance layer. When the program voltage may be lower than a voltage of the ground electrode, the charge bypass layer may bypass the oxygen vacancies generated from the ground electrode to a horizontal grain boundary, which may be substantially perpendicular to the vertical electric field, to restrain the oxygen vacancies in the horizontal grain boundary of the charge bypass layer.

According to example embodiments, there may be provided a method of manufacturing a resistive memory cell. In the method of manufacturing the resistive memory cell, a lower electrode may be formed. A seed layer may be formed on the lower electrode. A charge bypass layer including a conductive 2D material layer may be formed using the seed layer. A variable resistance layer may be formed on the charge bypass layer. An oxygen vacancy layer may be formed on the variable resistance layer. An upper electrode may be formed on the oxygen vacancy layer.

In example embodiments, the seed layer may include graphene.

According to example embodiments, in order to prevent a reset error of memory cells in the resistive memory device, the charge bypass layer, which may include the at least one conductive 2D material layer, may be interposed between the electrode having a relatively high voltage, for example, the lower electrode and the variable resistance layer. Undesired generated charges in the variable resistance layer and the lower electrode adjacent to each other in a vertical direction may be bypassed by the charge bypass layer in a horizontal direction. Thus, charge exchanges between the variable resistance layer and the lower electrode may be blocked so that an undesired abnormal filament may not be generated. As a result, in a reset operation, the variable resistance layer may be maintained as a high resistance state.

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIG. 1 is a block diagram illustrating a resistive memory device in accordance with embodiments of the disclosure;

FIG. 2 is a perspective view illustrating a part of a resistive memory array in accordance with embodiments of the disclosure;

FIG. 3 is a cross-sectional view illustrating a resistance memory cell in accordance with embodiments of the disclosure;

FIG. 4 is a view illustrating grains of a charge bypass layer in accordance with embodiments of the disclosure;

FIGS. 5A to 5C are cross-sectional views illustrating charge bypass layers in accordance with embodiments of the disclosure;

FIG. 6 is a cross-sectional view illustrating a resistive memory cell for explaining a set program operation in accordance with embodiments of the disclosure;

FIG. 7 is a cross-sectional view illustrating a resistive memory cell for explaining a reset program operation in accordance with embodiments of the disclosure;

FIG. 8 is a cross-sectional view illustrating a resistive memory cell for explaining a read operation in accordance with embodiments of the disclosure;

FIG. 9 is a flow chart illustrating a method of manufacturing a resistive memory cell of a resistive memory device in accordance with embodiments of the disclosure;

FIG. 10 is a flow chart illustrating a step for forming a charge bypass layer of FIG. 9; and

FIGS. 11 to 14 are cross-sectional views illustrating a method of manufacturing a resistive memory cell in accordance with embodiments of the disclosure.

### DETAILED DESCRIPTION

Various embodiments of the present disclosure will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes, which do not depart from the spirit and scope of the present invention as defined in the appended claims.

The present invention is described herein with reference to cross-section and/or plan illustrations of idealized embodiments of the present invention. However, embodiments of the present invention should not be construed as limiting the inventive concepts. Although a few embodiments of the present invention will be shown and described, it will be appreciated by those of ordinary skill in the art that changes may be made in these embodiments without departing from the principles and spirit of the present invention.

As used herein, the term “configured” refers to a size, shape, material composition, orientation, or arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to a major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, spatially relative terms, such as “beneath,” “below,” “bottom,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” may encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, the phrase “coupled to” and “connected to” refer to structures operatively connected with each other, such as electrically connected through a direct Ohmic connection or through an indirect connection (e.g., by way of another structure).

A resistive memory device of example embodiments may be applied to a neural network system. The resistive memory device may include a resistive memory array and a circuit block configured to control the resistive memory array. The resistive memory array may include a plurality of resistive memory cells having a charge bypass layer. The charge bypass layer may be interposed between a variable resistance layer and an electrode having a relatively high voltage to block exchanges of charges, such as for example oxygen vacancies and oxygen ions, between the electrode and the variable resistance layer. The charge bypass layer may include at least one two-dimensional (2D) conductive or semiconductor layer. The 2D conductive or semiconductor layer may include a plurality of discontinuous vertical grain boundaries and a plurality of horizontal grain boundaries connected between the discontinuous vertical grain boundaries and may be arranged so that a diffusion path of the charge bypass layer may include the horizontal grain boundaries positioned between adjacent discontinuous vertical grain boundaries as well as the plurality of discontinuous vertical grain boundaries. Thus, the oxygen vacancies and the oxygen ions that are between the electrode and the vertically adjacent variable resistance layer may diffuse along the horizontal grain boundaries.

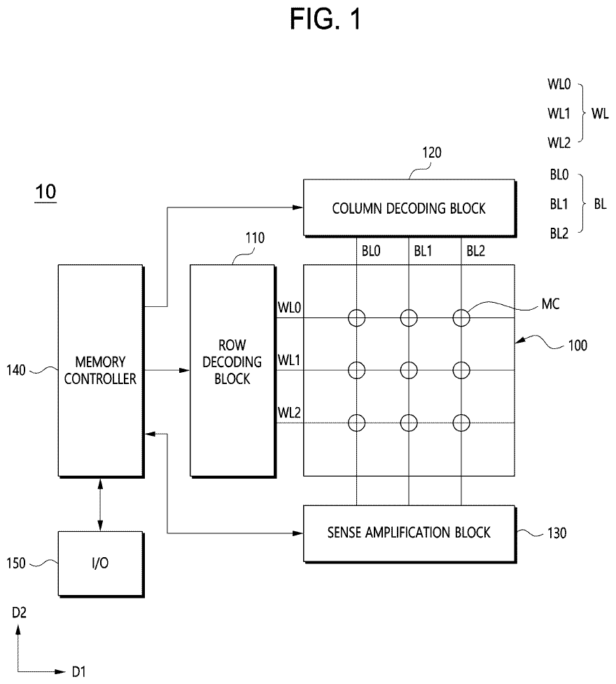

FIG. 1 is a block diagram illustrating a resistive memory device in accordance with embodiments of the disclosure.

Referring to FIG. 1, a resistive memory device 10 may include a resistive memory array 100, a row decoding block 110, a column decoding block 120, a sense amplification block 130, a memory controller 140 and an input/output circuit block 150.

The resistive memory array 100 may include a plurality of

resistive memory cells MC. The resistive memory cells MC may be programmable to different logic states. In embodiments, each of the resistive memory cells MC may be programmed to two states, low resistance and high resistance, represented by a logic 0 (for example, logic low) and a logic 1 (for example, logic high). The resistive memory cell MC may be reversibly switched to a low resistance state and a high resistance state.

In embodiments, the resistive memory cells MC may be arranged in a neural memory unit for imitating neural network functions such as a learning function, for example, a cross point array shape.

In embodiments, the resistive memory cell MC may include a variable resistance layer. The variable resistance layer may be changed to the low resistance state (hereinafter, referred to as a set state) or the high resistance state (hereinafter, referred to as a reset state) in accordance with an applying voltage and a shape of the applying voltage.

Changes in a voltage that alters the characteristics of the variable resistance layer may be applied, i.e., a change of a threshold voltage may indicate a synapse weight in a neuromorphic system. A change in synapse weight may represent or be interpreted by the learning and may be analogous to changes in biological synapse functions.

The resistive memory array 100 may include a plurality of word lines WL0˜WL2 and a plurality of bit lines BL0˜BL2. In embodiments, the word lines WL0˜WL2 and the bit lines BL0˜BL2 may be intersected with each other. The resistive memory cells MC may be connected to intersected portions between the word lines WL0˜WL2 and the bit lines BL0˜Bl2. The intersected portion may correspond to an address of a resistive memory cell MC.

In embodiments, when a resistive memory cell MC is selected, programmed or read, all of a word line and a bit line connected to the resistive memory cell MC may be activated. The resistive memory cell MC will be explained in detail below.

The row decoding block 110 and the column decoding block 120 may select a resistive memory cell MC. For example, the row decoding block 110 may receive a row address from the memory controller 140. The row decoding block 110 may activate the word line WL based on the row address. The column decoding block 120 may receive a column address from the memory controller 140. The column decoding block 120 may active the bit line BL based on the column address. Thus, the resistive memory cell MC, which may be connected to the activated word line WL and the activated bit line BL, may be accessed to perform a memory operation.

The sense amplification block 130 may determine a program state of the resistive memory cell MC, for example, a resistance state. The sense amplification block 130 may detect a current flow through the resistive memory cell MC to sense information in the selected resistive memory cell MC. The sense amplification block 130 may sense the resistance state as logic low (low resistance state) or logic high (high resistance state) using the current flow of through resistive memory cell MC.

The memory controller 140 may control operations of resistive memory cells MC such as read operations, write operations, etc., through various elements such as the row decoding block 110, the column decoding block 120 and the sense amplification block 130. For example, the memory controller 140 may receive various commands from an external device to generate a row address and a column address for selecting a resistive memory cell MC. Further, the memory controller 140 may generate and control various voltages or current used for operations of the resistive memory array 100.

The input/output circuit block 150 may be arranged to facilitate the exchange of signals between the row decoding block 110 and the memory controller 140, between the column decoding block 120 and the memory controller 140, and between the sense amplification block 130 and the memory controller 140.

The resistive memory cells MC in the resistive memory array 100 may be grouped into memory units, such as for example neural memory units for storing analog data. Thus, the memory controller 140 may be connected to a neural memory unit. Therefore, the memory controller 140 may be a neural memory unit controller. Neural memory units may be configured and arranged to imitate a neural network architecture.

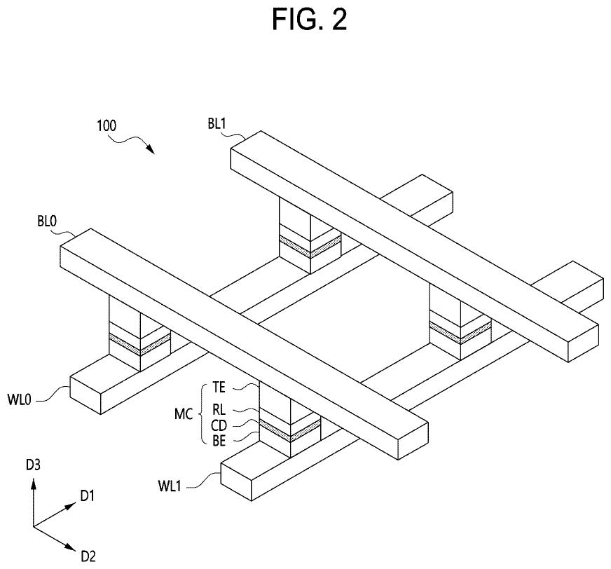

FIG. 2 is a perspective view illustrating a part of a resistive memory array in accordance with embodiments of the disclosure.

Referring to FIG. 2, word lines WL0 and WL1 of a resistive memory array 100 may be arranged in parallel in a first direction D1. The bit lines BL0 and BL1 of the resistive memory array 100 may be positioned on a plane different from a plane on which the word lines WL0 and WL1 are positioned. The bit lines BL0 and Bl1 may be arranged in parallel to each other. The bit lines BL0 and BL1 may extend in a direction that intersects with the first direction D1, for example, a second direction D2.

As described above, resistive memory cells MC may be positioned at intersected portions between the bit lines BL0 and BL1 and the word lines WL0 and WL1. Each resistive memory cell MC may include a lower electrode BE, a charge bypass layer CD, a variable resistance layer RL and an upper electrode TE.

The lower electrode BE may be electrically connected to the word lines WL0 and WL1. The upper electrode TE may be electrically connected to the bit lines BL0 and BL1. Alternatively, the lower electrode BE may be electrically connected to the bit lines BL0 and BL1 and the upper electrode TE may be electrically connected to the word lines WL0 and WL1.

The variable resistance layer RL may include a material having a resistance that can be changed by a voltage difference between the upper electrode TE and the lower electrode BE, i.e., a vertical electric field between the upper electrode TE and the lower electrode BE.

The upper electrode TE may include an oxygen vacancy storage layer for generating a charge, such as for example an oxygen vacancy.

The charge bypass layer CD may block an exchange of oxygen vacancies or oxygen ions between the lower electrode BE and the variable resistance layer RL. The charge bypass layer CD will be explained in greater detail below.

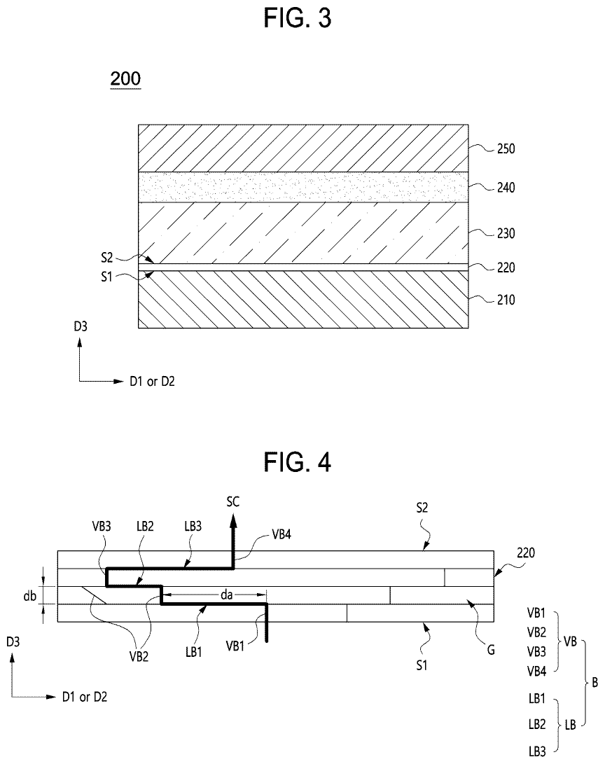

FIG. 3 is a cross-sectional view illustrating a resistance memory cell in accordance with embodiments of the disclosure and FIG. 4 is a view illustrating grains of a charge bypass layer in accordance with embodiments of the disclosure.

Referring to FIG. 3, a resistive memory cell 200 may include a lower electrode 210, a charge bypass layer 220, a variable resistance layer 230, an oxygen vacancy storage layer 240 and an upper electrode 250.

The lower electrode 210 may include at least one of W, Au, Pt, Pd, Rh, Ir, Ru, Ti, Ta, Mo, Cr and V, a nitride including one or more of the above-mentioned metals, a silicon compound including one or more of the above-mentioned metals, an oxide including one or more of the above-mentioned metals, etc.

The charge bypass layer 220 may be positioned between the lower electrode 210 and the variable resistance layer 230. The charge bypass layer 220 may block undesired exchanges of oxygen vacancies and oxygen ions between the lower electrode 210 and the variable resistance layer 230.

In embodiments, the charge bypass layer 220 may bypass the oxygen vacancies generated from the lower electrode 210 in horizontal directions D1 and D2, and not in a vertical direction D3 in the direction of the variable resistance layer 230. Further, the charge bypass layer 220 may prevent the oxygen ions in the variable resistance layer 230 from diffusing in the vertical direction D3 in the direction of the lower electrode 210.

The charge bypass layer 220 may include at least one 2D material layer with a conductivity. As shown in FIG. 4, the charge bypass layer 220 may include a plurality of grain boundaries B configured to define a plurality of grains G. In example embodiments, the grain boundaries B of the charge bypass layer 220 may be diffusion paths of the oxygen vacancies and the oxygen ions (hereinafter, referred to as charges).

In embodiments, the grain boundaries B of the charge bypass layer 220 may include a vertical grain boundary VB and a horizontal grain boundary LB. The vertical grain boundary VB may include boundaries extending in diagonal lines through which the charges may be transferred toward a lower surface S2 of the variable resistance layer 230 from an upper surface S1 of the lower electrode 210 or toward the upper surface S1 of the lower electrode 210 from the lower surface S2 of the variable resistance layer 230 as well as in the third direction D3 substantially perpendicular to the upper surface S1 of the lower electrode 210. The horizontal grain boundary LB may include boundaries extending in directions substantially parallel to the surface of the lower electrode 210.

In embodiments, the vertical grain boundary VB of the charge bypass layer 220 may include a plurality of vertical grain boundaries VB1, VB2, VB3 and VB4. A plurality of horizontal grain boundaries LB1, LB2 and LB3 may be inserted into spaces between vertically adjacent vertical grain boundaries (e.g., VB1, VB2, VB3 and VB4).

For example, reference numeral SC in FIG. 4 may represent the shortest diffusion path of a charge through the charge bypass layer 220. The shortest diffusion path SC may be longer than a summed length of the discontinuous vertical grain boundaries VB1, VB2, VB3 and VB4. That is, the shortest diffusion path SC may be a total of the summed length of the discontinuous vertical grain boundaries VB1, VB2, VB3 and VB4 and a summed length of the discontinuous horizontal grain boundaries LB1, LB2 and LB3.

Alternatively, a length da of at least one among the horizontal grain boundaries LB1, LB2 and LB3, which are arranged between the discontinuous vertical grain boundaries VB1, VB2, VB3 and VB4, may be substantially equal to or greater than a length db of each of the discontinuous vertical grain boundaries VB1, VB2, VB3 and VB4. This results in a diffusion path for the charge that is longer than the vertical thickness of the charge bypass layer 220 and may be generally more elongated.

Further, lengths of the horizontal grain boundaries LB between adjacent vertical grain boundaries may be different from each other. Diffusion of the charges may be more or less delayed in proportion to the lengths of the horizontal grain boundary LB between adjacent the vertical grain boundaries VB.

That is, although the charges may enter into the charge bypass layer 220, the charges may be restrained by the vertical grain boundaries VB and the horizontal grain boundaries LB. Thus, the charges may not be easily transferred between the variable resistance layer 230 and the lower electrode 210.

In FIG. 4, grain G may have a quadrangular shape, but embodiments are not limited thereto. Alternatively, the grain G may have various shapes, sizes, and characteristics from the fabrication processes used to form the charge bypass layer 220.

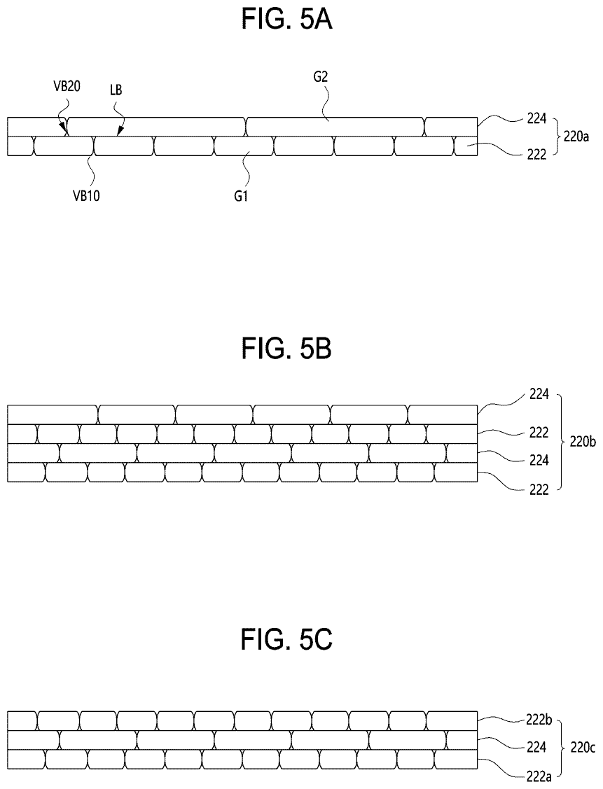

FIGS. 5A to 5C are cross-sectional views illustrating charge bypass layers in accordance with embodiments of the disclosure.

Referring to FIG. 5A, a charge bypass layer 220a may include at least one first 2D material layer 222 and at least one second 2D material layer 224. The 2D material layer may have a crystal lattice on a 2D plane. Further, a set of the crystal lattices growing from one crystal nucleus may be referred to as a grain.

For example, the first 2D material layer 222 may be formed on a lower electrode 210. The first 2D material layer 222 may have a semiconductor property. The semiconductor property may allow characteristics of first 2D material layer 222 to change between an insulator and a conductor in accordance with an applying voltage.

In embodiments, the first 2D material layer 222 may include a transition metal dichalcogenide (TMD). The transition metal in the TMD may include Mo, W, Pd, Pt, Ti, Zr, Hf, V, Nb, Ta, W, Tc, Re, Co, Rh, Ir, Ni, Zn, Sn, etc. The dichalcogenide in the TMD may include S, Se, Te, etc. For example, the dichalcogenide may include at least one of MoS2, MoSe2, WS2, WSe2, WTe2, MoTe2, ZrS2, ZrSe2, GaSe, GaTe2, HfS2, HfSe2, SnSe, PtSe2, PdSe2, PdTe2, ReSe2, VS2, VSe2, NbSe2, FeSe2 and FeTe2. The first 2D material layer 222 may have an energy band gap of about 0.3 eV to about 2.0 eV, independent of the above-mentioned materials.

The second 2D material layer 224 having conductivity may include an MXene material. The MXene material may have a constitutional formula of MaXb (where a and b are natural numbers). The M in the MXene may represent the at least one transition metal. The X in the MXene may include C or N.

For example, the M may include at least one of Sc, Y, Lu, Ti, Zr, Hf, V, Nb, Ta, Cr, Mo and W. In some embodiments, the MXene may include at least one of Ti2CdC, Sc2InC, Ti2AlC, Ti2GaC, Ti2InC, Ti2TIC, V2AlC, V2GaC, Cr2GaC, Ti2AlN, Ti2GaN, Ti2InN, V2GaN, Cr2GaN, Ti2GeC, Ti2SnC, Ti2PbC, V2GeC, Cr2AlC, Cr2GeC, V2PC, V2AsC, Ti2SC, Zr2InC, Zr2TIC, NLBAlC, NLBGaC, NLBInC, Mo2GaC, Zr2InN, Zr2TIN, Zr2SnC, Zr2PbC, NLBSnC, NLBPC, NLBAsC, Zr2SC, NLBSC, Hf2InC, Hf2TIC, Ta2AlC, Ta2GaC, Hf2SnC, Hf2PbC, Hf2SnN, Hf2SC; Ti3AlC2, V3AlC2, Ti3SiC2, Ti3GeC2, Ti3SnC2, Ta3AlC2; Ti4AlN3, V4AlC3, Ti4GaC3, Ti4SiC3, Ti4GeC3, Nb4AlC3 and Ta4AlC3.

The second 2D material layer 224 may include an MXene material having a single type 2D stratification or a stack type 2D stratification.

Because the first 2D material layer 222 and the second 2D material layer 224 may have the different properties, as shown in FIG. 5A, a size of a grain G1 in the first 2D material layer 222 may be different from a size of a gain G2 in the second 2D material layer 224.

For example, a vertical grain boundary VB10 of the first 2D material layer 222 and a vertical grain boundary VB20 of the second 2D material layer may be discontinuous. The horizontal grain boundary LB may be connected between the vertical grain boundaries VB10 and VB20 to elongate the transfer paths of the charges.

In FIG. 5A, the first 2D material layer 222 may be formed over the lower electrode 210. The second 2D material layer 224 may be formed under a variable resistance layer 230. Alternatively, the second 2D material layer 224 may be formed over the lower electrode 210, and the first 2D material layer 222 may be formed under the variable resistance layer 230.

Referring to FIG. 5B, a charge bypass layer 220b of some embodiments may include a first 2D material layer 222 and a second 2D material layer 224 that are alternately stacked at least twice.

Referring to FIG. 5C, a charge bypass layer 220c of some embodiments may include a first 2D lower layer 222a, a second 2D material layer 224 and a first 2D upper layer 222b, sequentially stacked.

The variable resistance layer 230 may be formed between the lower electrode 210 and an upper electrode 250. Particularly, the variable resistance layer 230 may be positioned between the charge bypass layer 220 and an oxygen vacancy storage layer 240. The variable resistance layer 230 may include a transition metal oxide. For example, the transition metal in the transition metal oxide may include at least one of Ta, Sc, Y, Ti, Zr, V, Cr, Nb, Os, Mn, Fe, Ni, Cu, Ag, Zn, Hf and W. Alternatively, the transition metal in the variable resistance layer 230 may include a material substantially the same as the material of the lower electrode 210, but embodiments are not limited thereto. For example, the variable resistance layer 230 may include perovskite oxide and switching characteristics of a resistance value may be represented by an electrical pulse. Alternatively, the variable resistance layer 230 may include any one of a single polar material representing a switching characteristic irrelevant to a polarity of an applying voltage, and a bipolar material representing opposite switching characteristics at different polarities, but embodiments are not limited thereto.

The variable resistance layer 230 may have a stoichiometric composition or an oxygen vacancy composition. The variable resistance layer 230 may include metal oxide having an oxidation potential energy higher than an oxidation potential energy of the oxygen vacancy storage layer 240. For example, when the oxygen vacancy storage layer 240 includes Ta, the variable resistance layer 230 may include hafnium oxide having an oxidation potential energy higher than an oxidation potential energy of tantalum oxide.

The oxygen vacancy storage layer 240 may be positioned between the variable resistance layer 230 and the upper electrode 250. The oxygen vacancy storage layer 240 may include a conductive material. For example, the oxygen vacancy storage layer 240 may have an optimal oxidation potential energy so that a metal or a metal oxide can be readily reversed in oxidation/reduction in accordance with directions of electric fields. The oxygen vacancy storage layer 240 may include at least one of Ta, Ti, Zr, V, W and Ru. Further, oxygen may be dissolved in the oxygen vacancy storage layer 240.

The resistive memory cell 200 may perform a memory operation by the exchanges of the oxygen ions and the oxygen vacancies between the oxygen vacancy storage layer 240 and the variable resistance layer 230.

The upper electrode 250 may face the lower electrode 210. The upper electrode 250 may be electrically connected to the oxygen vacancy storage layer 240. The upper electrode 250 may include at least one of W, Au, Pt, Pd, Rh, Ir, Ru, Ti, Ta, Mo, Cr and V, nitride including the above-mentioned metal, a silicon compound including the above-mentioned metal, oxide including the above-mentioned metal, etc.

The upper electrode 250 may include a conductive material having reactivity, with respect to an oxygen ion, that is higher than reactivity of the lower electrode 210. Thus, when the set/reset voltage may be applied to the upper electrode 250, an ionization in the upper electrode 250 may be generated more quickly than an ionization in the lower electrode 210.

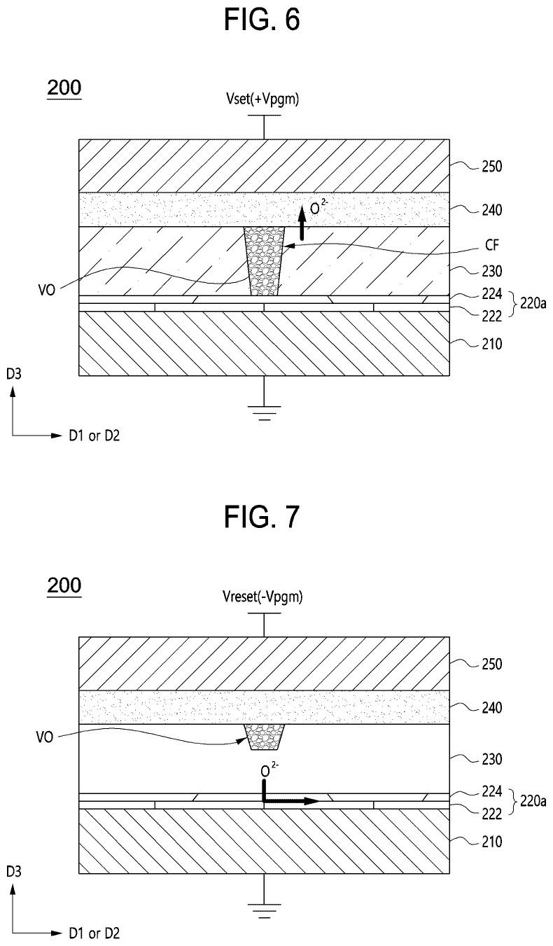

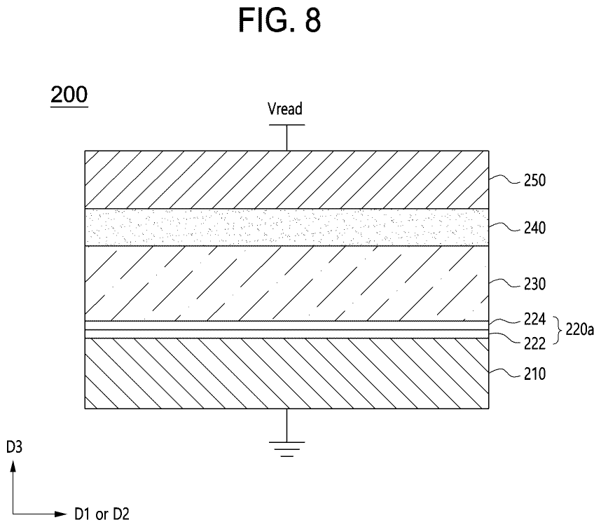

FIG. 6 is a cross-sectional view illustrating a resistive memory cell for explaining a set program operation in accordance with embodiments of the disclosure, FIG. 7 is a cross-sectional view illustrating a resistive memory cell for explaining a reset program operation in accordance with embodiments of the disclosure and FIG. 8 is a cross-sectional view illustrating a resistive memory cell for explaining a read operation in accordance with embodiments of the disclosure. A resistive memory cell 200 in FIGS. 6 and 7 may include a structure of a charge bypass layer 220a.

Referring to FIG. 6, a positive program voltage +Vpgm, such as for example a set voltage Vset, may be applied to the upper electrode 250. A ground voltage may be applied to the lower electrode 210. Thus, the upper electrode 250 may be a program electrode. The lower electrode 210 may be a ground electrode. When a voltage difference between the set voltage Vset and the ground voltage is no less than a threshold voltage, an electrochemical reaction of the oxygen vacancy storage layer 240 may be induced to generate oxygen vacancies Vo.

Oxygen ions O²⁻ in the variable resistance layer 230 and the oxygen vacancies Vo in the oxygen vacancy storage layer 240 may be exchanged with each other under an electric field between the upper electrode 250 and the lower electrode 210. Thus, a conductive filament CF including the oxygen vacancies Vo may be generated in the variable resistance layer 230. The conductive filament CF may be formed through the variable resistance layer 230 so that the conductive filament CF may act as a current path. Therefore, a resistance of the variable resistance layer 230 may be decreased so that the resistive memory cell 200 may be switched to the low resistance state, i.e., the set state.

Referring to FIG. 7, a negative program voltage −Vpgm, such as for example a reset voltage Vreset, may be applied to the upper electrode 250. The ground voltage may be applied to the lower electrode 210. When a voltage difference between the reset voltage Vreset and the ground voltage is no less than the threshold voltage, the oxygen vacancies Vo in the variable resistance layer 230 may be transferred to the oxygen vacancy storage layer 240 representing a relatively negative potential, and the conductive filament CF may be broken. Therefore, the conductive filament CF as the current path may be cut to increase the resistance of the variable resistance layer 230. As a result, the resistive memory cell 200 may be switched to the high resistance state, i.e., the reset state.

However, because the upper electrode 250 may receive the voltage having the negative potential level in resetting the resistive memory cell 200, the lower electrode 210 may represent a relatively high potential level. Thus, the oxygen ions O²⁻ in the variable resistance layer 230, including the metal oxide and oxygen ions O²⁻ in insulating interlayers, may be transferred to a surface of the lower electrode 210. Similarly, because the lower electrode 210 may include metal, an electric ion reaction for bonding the oxygen ions O²⁻ may be generated to generate desired oxygen vacancies.

When the lower electrode 210 may directly contact the variable resistance layer 230 without the charge bypass layer 220, the oxygen vacancies Vo and the oxygen ions O²⁻ may be exchanged between the lower electrode 210 and the variable resistance layer 230. The undesired exchanges of the oxygen vacancies Vo and the oxygen ions O²⁻ may result in re-establishing the broken conductive filament. Thus, although the variable resistance layer 230 may represent the high resistance state by the reset voltage Vreset, in this instance a negative set for maintaining the low resistance state may be generated by the abnormal conductive filament.

In contrast, when the charge bypass layer 220 is interposed between the lower electrode 210 and the variable resistance layer 230, the diffusion of the remaining oxygen ions O²⁻ in the variable resistance layer 230 toward the lower electrode 210 may be blocked. Further, the diffusion of the oxygen vacancies Vo in the lower electrode 210 toward the variable resistance layer 230 may also be blocked. That is, although the oxygen vacancies Vo and the oxygen ions O²⁻ may diffuse into the charge bypass layer 220, the oxygen vacancies Vo and the oxygen ions O²⁻ may be restrained by the vertical and horizontal grain boundaries in the charge bypass layer 220 to block the diffusion of the oxygen vacancies Vo and the oxygen ions O²⁻ toward the variable resistance layer 230 and the lower electrode 210.

Further, because the lower electrode 210 may have a reactivity lower than the reactivity of the upper electrode 250, the timing of the generation of oxygen vacancies may be delayed. That is, the diffusion of the oxygen vacancies Vo and the oxygen ions O²⁻ may be blocked, together with the delay of the timing for generating the oxygen vacancies, so that the abnormal filament may not be generated in the variable resistance layer 230.

Furthermore, because the charge bypass layer 220 may have conductivity, losses of the set voltage and the reset voltage caused by the charge bypass layer 220 may not be generated.

After the set program operation and/or the reset program operation, as shown in FIG. 8, a read voltage Vread may be applied to the upper electrode 250. The ground voltage may be applied to the lower electrode 210. The read voltage Vread may function to induce flow a current between the upper electrode 250 and the lower electrode 210 without a resistance change of the variable resistance layer 230. The current flowing from the lower electrode 210 to the upper electrode 250, measured using a sensor electrically connected to the upper electrode 250, may read the resistance state of the resistive memory cell 200.

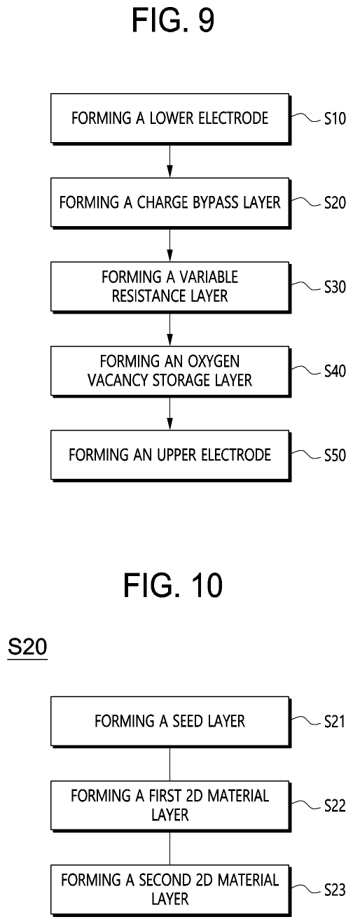

FIG. 9 is a flow chart illustrating a method of manufacturing a resistive memory cell of a resistive memory device in accordance with embodiments of the disclosure, FIG. 10 is a flow chart illustrating a step for forming a charge bypass layer of FIG. 9 and FIGS. 11 to 14 are cross-sectional views illustrating a method of manufacturing a resistive memory cell in accordance with embodiments of the disclosure.

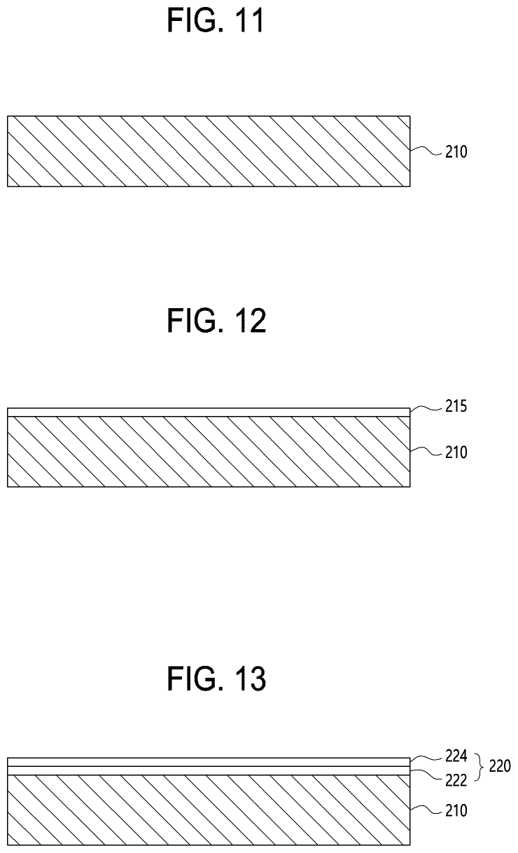

Referring to FIGS. 9 and 11, in step S10 of FIG. 9, a lower electrode 210 may be formed. The lower electrode 210 may include W, Au, Pt, Pd, Rh, Ir, Ru, Ti, Ta, Mo, Cr, V, the above-mentioned metal nitride, the above-mentioned metal silicon, the above-mentioned metal oxide, a combination thereof, etc. The lower electrode 210 may be formed by a chemical vapor deposition (CVD) process, a metal organic CVD (MOCVD) process, an atomic layer deposition (ALD) process, etc. The lower electrode 210 may include a junction region having conductive impurities.

Referring to FIGS. 9, 10, 12 and 13, in step S20 of FIG. 9, a charge bypass layer 220 may be formed on a lower electrode 210. Particularly, in step S21 of FIG. 10, a seed layer 215 may be formed on the lower electrode 210. For example, the seed layer 215 may include a graphene layer. The graphene layer may be a nano-crystalline 2D material layer having a uniform hexagonal honeycomb lattice. The graphene layer may be formed by a CVD process, an MOCVD process, an ALD process, etc.

In step S22 of FIG. 10, a first 2D material layer 222 may be formed using the graphene layer as the seed layer 215. The first 2D material layer 222 may have semiconductor properties. For example, the first 2D material layer 222 may include the transition metal dichalcogenide. Because the first 2D material layer 222 may be formed using the graphene layer with the uniform nano-crystalline lattices as the seed layer 215, the first 2D material layer 222 may have uniform grain boundaries.

In step S23 of FIG. 10, a second 2D material layer 224 may be formed on the first 2D material layer 222. The second 2D material layer 224 may be formed by a CVD process, an MOCVD process, an ALD process, etc. Because a property of the second 2D material layer 224 may be different from a property of the first 2D material layer 222, the second 2D material layer 224 may have a grain arrangement and a grain boundary arrangement different from those of the first 2D material layer 222. However, because the second 2D material layer 224 may be formed based on the first 2D material layer 222 with a uniform grain, the second 2D material layer 224 may also have a uniform grain arrangement.

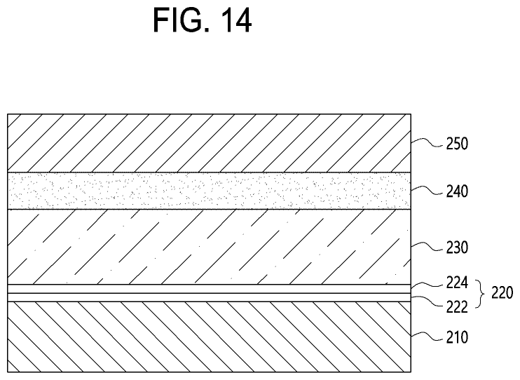

Referring to FIGS. 9 and 14, in step S30 of FIG. 9, a variable resistance layer 230 may be formed on the second 2D material layer 224. As mentioned above, the variable resistance layer 230 may include the transition metal oxide. For example, the variable resistance layer 230 may be formed by a CVD process, an MOCVD process, an ALD process, etc.

In step S40 of FIG. 9, an oxygen vacancy storage layer 240 may be formed on the variable resistance layer 230. As mentioned above, the oxygen vacancy storage layer 240 may include a metal or a metal compound having an oxidation potential energy lower than the oxidation potential energy of the variable resistance layer 230. Thus, because the oxygen vacancy storage layer 240 may have relatively low oxidation potential energy, the electrochemical reaction may be rapidly generated by applying the voltage or the current. For example, the oxygen vacancy storage layer 240 may be formed by a CVD process, an MOCVD process, an ALD process, etc.

In step S50 of FIG. 9, an upper electrode 250 may be formed on the oxygen vacancy storage layer 240. The upper electrode 250 may include a metal-containing material having a reactivity higher than the reactivity of the lower electrode 210.

According to example embodiments, in order to prevent a reset error of memory cells in a resistive memory device, a charge bypass layer, which may include at least one conductive 2D material layer, may be interposed between an electrode having a relatively high voltage, for example, a lower electrode and a variable resistance layer. Undesired generated charges in the variable resistance layer and the lower electrode adjacent to each other in a vertical direction may be bypassed by the charge bypass layer in a horizontal direction. Thus, charge exchanges between the variable resistance layer and the lower electrode may be blocked so that an undesired abnormal filament may not be generated. As a result, in a reset operation, the variable resistance layer may be maintained as a high resistance state.

In example embodiments, the resistive memory array may be applied to the analog memory such as the neural network system, but not limited thereto. For example, the resistive memory array of example embodiments may be applied to memory devices of various semiconductor systems.

Further, the charge bypass layer may be interposed between the lower electrode and the variable resistance layer, but not limited thereto. For example, the lower electrode making contact with the charge bypass layer may be an electrode having a relatively high potential.

The above described embodiments of the present invention are intended to illustrate and not to limit the present invention. Various alternatives and equivalents are possible. The invention is not limited by the embodiments described herein. Nor is the invention limited to any specific type of semiconductor device. Another additions, subtractions, or modifications are obvious in view of the present disclosure and are intended to fall within the scope of the appended claims.

What is claimed is:

1. A resistive memory cell comprising:
a lower electrode;
an upper electrode arranged substantially perpendicular to the lower electrode;
a variable resistance layer interposed between the lower electrode and the upper electrode, the variable resistance layer having a resistance changed by a conductive filament, which includes reversibly generated oxygen vacancies, based on an electric field between the lower electrode and the upper electrode; and
a charge bypass layer interposed between the lower electrode and the variable resistance layer,
wherein the charge bypass layer comprises:
a plurality of discontinuous vertical grain boundaries; and
at least one horizontal grain boundary connected between adjacent discontinuous vertical grain boundaries.

2. The resistive memory cell of claim 1, wherein the charge bypass layer bypasses charges, which are generated in the lower electrode and the variable resistance layer by applying a voltage higher than a program voltage to the lower electrode, in a horizontal direction to block exchanges of the charges between the lower electrode and the variable resistance layer.

3. The resistive memory cell of claim 2, wherein the horizontal grain boundary has a length longer than a length of each of the vertical grain boundaries.

4. The resistive memory cell of claim 1, wherein the charge bypass layer comprises at least one conductive two-dimensional (2D) layer.

5. The resistive memory cell of claim 4, wherein the charge bypass layer comprises a plurality of stacked 2D material layers, each of the plurality of stacked 2D material layers comprising different grains.

6. The resistive memory cell of claim 4, wherein the charge bypass layer comprises:
at least one 2D semiconductor layer; and
at least one conductive 2D material layer.

7. The resistive memory cell of claim 6, wherein the at least one conductive 2D material layer comprises at least one of Ti2CdC, Sc2InC, TiZAlC, Ti2GaC, Ti2InC, Ti2TIC, V2AlC, V2GaC, Cr2GaC, TiZAlN, Ti2GaN, Ti2InN, V2GaN, Cr2GaN, Ti2GeC, Ti2SnC, Ti2PbC, V2GeC, Cr2AlC, Cr2GeC, V2PC, V2AsC, Ti2SC, Zr2InC, Zr2TIC, NLBAlC, NLBGaC, NLBInC, Mo2GaC, Zr2InN, Zr2TIN, Zr2SnC, Zr2PbC, NLBSnC, NLBPC, NLBAsC, Zr2SC, NLBSC, Hf2InC, Hf2TIC, Ta2AlC, Ta2GaC, Hf2SnC, Hf2PbC, Hf2SnN, Hf2SC; Ti3AlC2, V3AlC2, Ti3SiC2, Ti3GeC2, Ti3SnC2, Ta3AlC2; Ti4AlN3, V4AlC3, Ti4GaC3, Ti4SiC3, Ti4GeC3, Nb4AlC3 and Ta4AlC3.

8. The resistive memory cell of claim 6, wherein the at least one 2D semiconductor layer comprises a transition metal dichalcogenide including at least one of MoS2, MoSe2, WS2, WSe2, WTe2, MoTe2, ZrS2, ZrSe2, GaSe, GaTe2, HfS2, HfSe2, SnSe, PtSe2, PdSe2, PdTe2, ReSe2, VS2, VSe2, NbSe2, FeSe2 and FeTe2.

9. The resistive memory cell of claim 1, further comprising an oxygen vacancy storage layer interposed between the variable resistance layer and the upper electrode to selectively generate oxygen vacancies based on a program voltage.

10. The resistive memory cell of claim 1, wherein at least one of the lower electrode and the upper electrode comprises at least one of a metal including at least one of W, Au, Pt, Pd, Rh, Ir, Ru, Ti, Ta, Mo, Cr and V, nitride including the metal, a silicon compound including the metal and oxide including the metal.

11. The resistive memory cell of claim 10, wherein the upper electrode comprises a material having reactivity with respect to an oxygen ion that is higher than reactivity of the lower electrode.
